(19) United States
(12) Patent Application Publication
(10) Pub. No.: US 2013/0335110 A1
(43) Pub. Date: Dec. 19, 2013

(54) PLANAR CIRCUIT TEST FIXTURE

(71) Applicant: Polyvalor, Limited Partnership, Montreal (CA)

(72) Inventors: Jules GAUTHIER, Laval (CA); Tarek DJERAFI, Montreal (CA); Ke WU, Montreal (CA); Andreas PATROVSKY, Freising (DE)

(21) Appl. No.: 13/919,767

(22) Filed: Jun. 17, 2013

Related U.S. Application Data
(60) Provisional application No. 61/660,255, filed on Jun. 15, 2012.

(51) Int. Cl. G01R 1/04

(52) U.S. Cl. CPC G01R 1/0408
USPC 324/750.25; 324/750.16

(57) ABSTRACT

There is provided a test fixture for testing a planar circuit. The test fixture comprises a body adapted to retain therein the planar circuit and to be connected to test equipment. The body provides a transition between the planar circuit and the test equipment and comprises a base member having a first surface and a fixation member having a second surface and connected to the base member through a first connection allowing movement along a first axis of the fixation member relative to the base member, a spacing defined between the first surface and the second surface for retaining therein an end of the planar circuit, the fixation member movable along the first axis relative to the base member for adjusting the spacing.

### CROSS-REFERENCE TO RELATED APPLICATIONS

This patent application claims priority under 35 USC §119(e) of U.S. Provisional Patent Application No. 61/660,255, filed on Jun. 15, 2012, the contents of which are hereby incorporated by reference.

### TECHNICAL FIELD

The present invention relates to the field of planar circuit testing, and, more particularly, to test fixtures for planar circuits.

### BACKGROUND OF THE ART

Within the radiofrequency (RF) and microwave industries, the testing of planar circuits, such as those made in Printed Circuit Board (PCB) or hybrid format, has been carried out on a daily basis in governmental and academic laboratories. Such testing requires accurate test set-ups to make fast and reliable measurements. Various test fixtures have been developed to enable such measurements. However, existing testing and measurement technologies suffer from a lack of flexibility with respect to the number and orientation of ports, which may be coupled to a planar circuit under test. Additional limitations in the size of the circuits, which may be accommodated by the test fixtures, further arise.

There is therefore a need for an improved test fixture for planar circuits.

### SUMMARY

In accordance with a first broad aspect, there is provided a test fixture for testing a planar circuit, the test fixture comprising a body adapted to retain therein the planar circuit and to be connected to test equipment, the body providing a transition between the planar circuit and the test equipment and comprising a base member having a first surface; and a fixation member having a second surface and connected to the base member through a first connection allowing movement along a first axis of the fixation member relative to the base member, a spacing defined between the first surface and the second surface for retaining therein an end of the planar circuit, the fixation member movable along the first axis relative to the base member for adjusting the spacing.

In accordance with a second broad aspect, there is provided a test bench for testing a planar circuit, the test bench comprising a first test equipment and at least one second test equipment; and a first test fixture and at least one second test fixture, the first test fixture comprising a first body adapted to retain therein a first end of the planar circuit and to be connected to the first test equipment and the at least one second test fixture comprising a second body adapted to retain therein a second end of the planar circuit opposite the first end and to be connected to the at least one second test equipment. The first and second body each comprise a base member having a first surface, and a fixation member having a second surface and connected to the base member through a first connection allowing movement along a first axis of the fixation member relative to the base member, a spacing defined between the first surface and the second surface for retaining therein a corresponding one of the first end and the second end of the planar circuit, the fixation member movable along the first axis relative to the base member for adjusting the spacing.

In accordance with a third broad aspect, there is provided a method for testing a planar circuit using a test fixture, the method comprising displacing along a first axis a fixation member of the test fixture relative to a base member of the test fixture, the fixation member connected to the base member through a first connection allowing movement along the first axis of the fixation member relative to the base member, the base member having a first surface and the fixation member having a second surface, a spacing defined between the first surface and the second surface and adapted to receive therein the planar circuit, positioning the planar circuit within the spacing, securing the fixation member in place relative to the base member, thereby retaining the planar circuit within the spacing, and connecting test equipment to the test fixture for testing the planar circuit.

### BRIEF DESCRIPTION OF THE DRAWINGS

Further features and advantages of the present invention will become apparent from the following detailed description, taken in combination with the appended drawings, in which:

FIG. 1 is a top perspective view of a test bench comprising a SIW to waveguide test fixture, in accordance with an illustrative embodiment of the present invention;

FIG. 2a is a side perspective view of the SIW to waveguide test fixture of FIG. 1;

FIG. 2b is a schematic view of the SIW to waveguide test fixture of FIG. 2a receiving a SIW circuit;

FIG. 3 is a schematic diagram of an impedance matching transformer of the SIW to waveguide test fixture of FIG. 1;

FIG. 4 is a plot of the power transferred and reflected by the SIW to waveguide test fixture of FIG. 1;

FIG. 5a is a front perspective view of a test bench comprising a first and a second planar circuit to coaxial test fixture, in accordance with an illustrative embodiment of the present invention;

FIG. 5b is a detailed view of the first and second planar circuit to coaxial test fixtures of FIG. 5a;

FIG. 6a is a side perspective view of one of the planar circuit to coaxial test fixtures of FIG. 5a;

FIG. 6b is a front perspective view of one of the planar circuit to coaxial test fixtures of FIG. 5a;

FIG. 6c is a top front perspective view of one of the planar circuit to coaxial test fixtures of FIG. 5a with a circuit under test coupled thereto;

FIG. 6d is a rear perspective view of one of the planar circuit to coaxial test fixtures of FIG. 5a;

FIG. 7a is a front perspective view of a pair of planar circuit to coaxial test fixtures coupled to a circuit under test in a side-by-side relationship, in accordance with an illustrative embodiment of the present invention;

FIG. 7b is a rear perspective view of the pair of planar circuit to coaxial test fixtures of FIG. 7a;

FIG. 8a is a front perspective view of a pair of planar circuit to coaxial test fixtures coupled to a circuit under test in an orthogonal relationship, in accordance with an illustrative embodiment of the present invention;

FIG. 8b is a top view of the pair of planar circuit to coaxial test fixtures of FIG. 8a;

FIG. 9a is a perspective view of a planar circuit to coaxial test fixture, in accordance with another illustrative embodiment of the present invention;

FIG. 9b is a perspective view of the planar circuit to coaxial test fixture of FIG. 9a in a disassembled configuration; and

FIG. 9c is a perspective view of assembly of a base member, a contact member, and a lever member of the test fixture of FIG. 9a.

It will be noted that throughout the appended drawings, like features are identified by like reference numerals.

### DETAILED DESCRIPTION

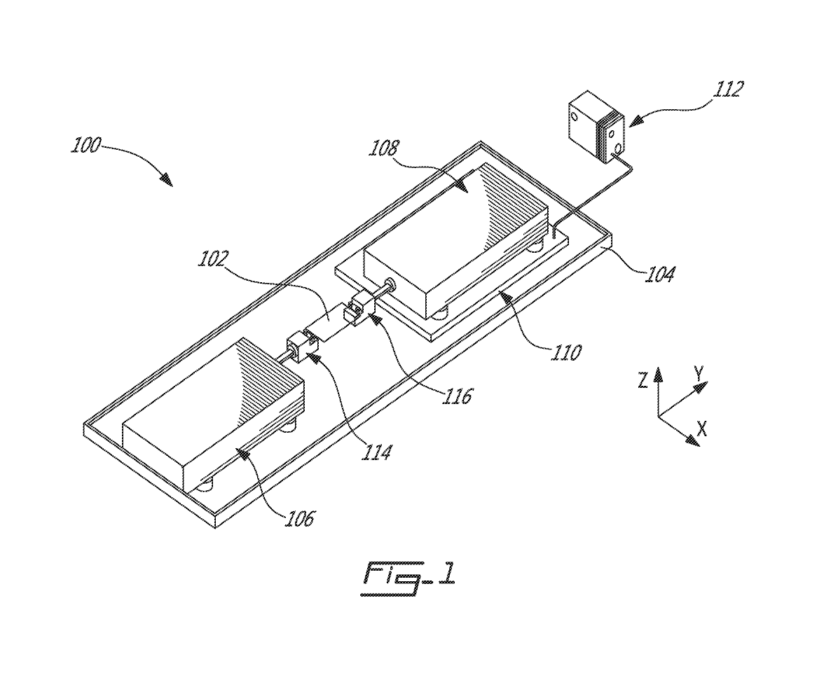

Referring to FIG. 1, a test bench 100 for testing a planar circuit 102 in accordance with a first illustrative embodiment will now be described. The planar circuit 102 may be a filter, transistor, diode, or other microwave device designed on a circuit using the substrate-integrated waveguide (SIW) technology. Although the description below refers to SIW circuits, it should be understood that other planar circuits, such as circuits using microstrip technology or coplanar waveguide structures, may also apply. The test bench 100 may be used at high frequencies, e.g. greater than or equal to 65 GHz. The test bench 100 illustratively comprises a support member 104, such as a table, onto which a first test equipment, such as a first network analyzer component 106 (e.g. a first up-down converter) and a second test equipment, such as a second network analyzer component 108 (e.g. a second up-down converter) are positioned. It should be understood that, depending on the planar circuit 102 being tested and on the measurements to be obtained, test equipment other than the network analyzer components 106 and 108, for example spectrum analyzers or noise analyzers, may also apply.

The first network analyzer component 106 is illustratively fixedly positioned on the support member 104 using fasteners (not shown), such as screws or the like. The second network analyzer component 108 is illustratively coupled to an air floating base 110 positioned on the support member 104. For this purpose, an air compressor 112 is illustratively coupled to the floating base 110 and generates air flow for enabling flotation of the base 110 relative to the support member 104. As a result, the second network analyzer component 108 may be allowed to move along the X and Y axes in a friction-less manner. Once a desired position of the second network analyzer component 108 has been achieved, the air compressor 112 may be turned off to lock the second network analyzer component 108 in the desired position.

In order to connect the circuit under test 102 to the first and second network analyzer components 106 and 108, which may be connected to a standard waveguide interface (not shown), a first and a second test fixture 114 and 116 are illustratively provided. The first test fixture 114 is illustratively coupled to the first network analyzer component 106 and to a first edge (not shown) of the circuit under test 102 while the second test fixture 116 is coupled to the opposite edge (not shown) of the circuit under test 102 and to the second network analyzer component 108.

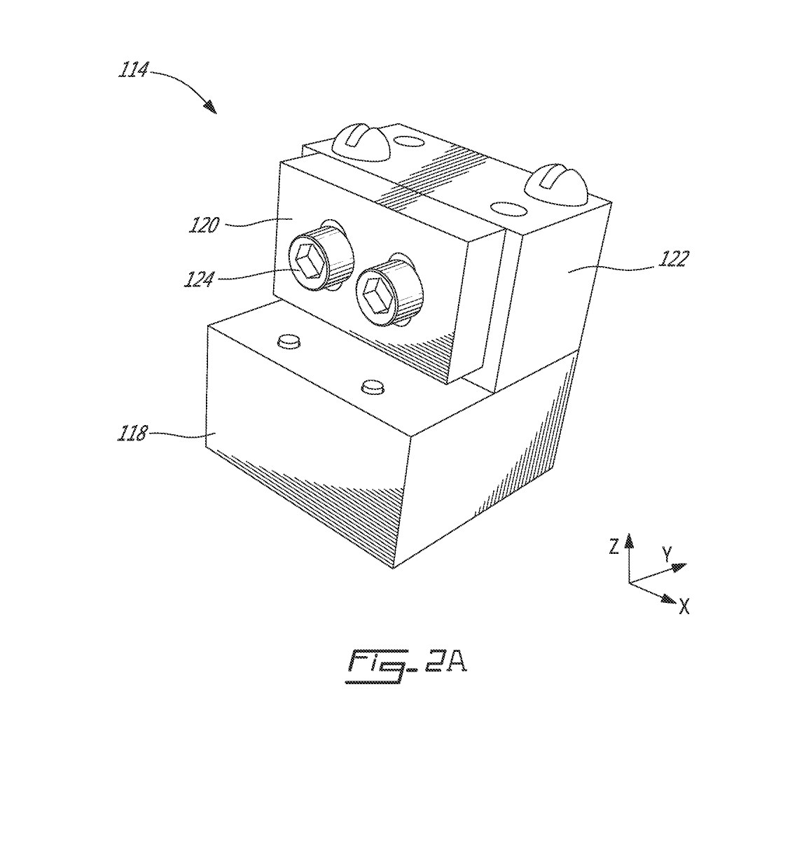

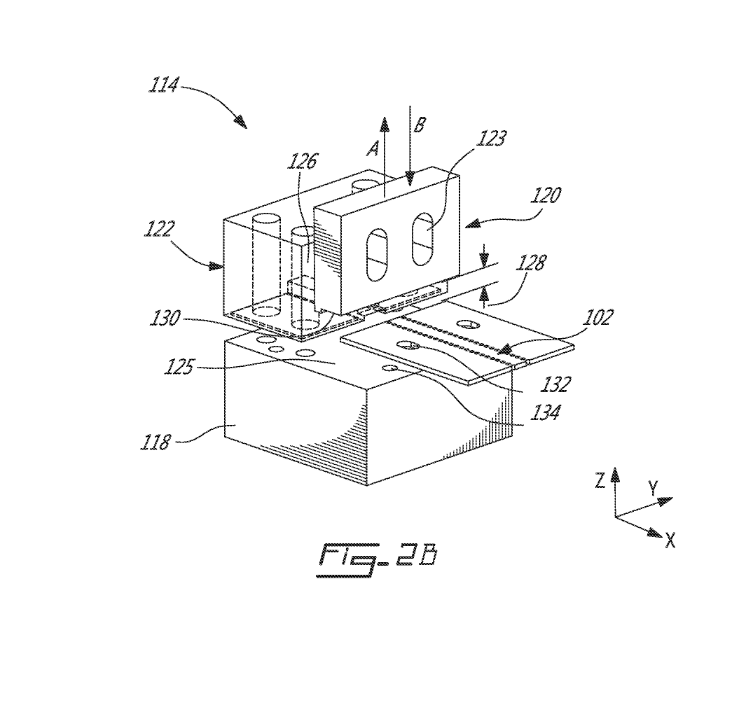

Referring to FIG. 2a and FIG. 2b, the first test fixture 114, which illustratively corresponds to the second test fixture 116, will now be described. The test fixture 114 illustratively comprises a base member 118 and a fixation member 120, such as a metal cove. The base member 118 and the fixation member 120 are illustratively made of metal, such as aluminum or any other suitable material known to those skilled in the art, to ensure proper ground contact. The fixation member 120 is illustratively movable relative to the base member 118 and provides a suitable transition between a standard rectangular waveguide 122 and the SIW circuit under test 102. For this purpose, one or more elongate apertures or slots as in 123 are formed in the fixation member 120 and are each adapted to receive therein a fastener 124, such as a screw, for attaching the fixation member 120 to the waveguide 122. Although screws are described herein, it should be understood that other suitable fasteners, such as pins, or the like, may apply. Each aperture 123 illustratively extends along the Z axis and is sized and shaped to allow displacement of the fixation member 120 relative to the base member 118 along the Z axis, as will be discussed further below. Fasteners, such as screw, bolts, and the like, (not shown) are further be provided for attaching the waveguide 122 to the base member 118. Although the waveguide 122 has been illustrated as a rectangular waveguide, it should be understood that other waveguides may apply.

With the waveguide 122 positioned on a support surface 125 of the base member 118, the fixation member 120 may be adapted to slide along the Z axis against a surface 126 of the waveguide 122, the surface 126 being substantially perpendicular to the support surface 125. Indeed, each elongate aperture 123 is configured to have a dimension along the Z axis, e.g. a length, greater than the dimension of the corresponding fastener 124 along the Z axis. In this manner, the fixation member 120 is allowed to move in the direction of the Z axis while the fasteners 124 remains retained within the aperture 123. For this purpose, the fasteners 124 may need to be actuated in a first direction, e.g. slightly loosened, to enable sliding of the fixation member 120 relative to the base member 118 and the waveguide 122. Such movement of the fixation member 120 may be effected manually or using any other suitable means. Once the fixation member 120 has reached a desired position, the fasteners 124 may be actuated in a second direction opposite to the first direction, e.g. tightened, to secure the fixation member 120 in place. Although two apertures 123 and fasteners 124 have been illustrated, it should be understood that other configurations may apply. Still, it may be desirable to provide more than one aperture 123 and corresponding fastener 124 to provide stability to the fixation member 120 during displacement thereof. The elongate configuration of the apertures 123 ensures that the fixation member 120 remains secured to the waveguide 122 during the displacement. As will be apparent to those skilled in the art, the fixation member 120 can only be displaced until the fastener 124 reaches an end (not shown) of the aperture 123. It will also be apparent that other connections for enabling movement of the fixation member 120 relative to the base member 118 may apply.

In this manner and as shown in FIG. 2b, the fixation member 120 may move along the direction of arrow A away from the support surface 125 of the base member 118 and thereby create a spacing 128 for receiving the SIW circuit under test 102 therein. Once the SIW circuit under test 102 is in place, the fixation member 120 may then be slid back along the direction of arrow B towards the support surface 125 of the base member 118 and the fastener (reference 124 in FIG. 2a) tightened to secure the position of the fixation member 120. As a result, the SIW circuit under test 102 may be held in place adjacent the waveguide 122 between the support surface 125 of the base member 118 and an inner surface 130 of the fixation member 120. Proper transition between the SIW circuit under test 102 and the waveguide 122 may be ensured by an impedance transformer (not shown) provided in the fixation member 120.

Provision of the movable fixation member 120 illustratively enables adjustment of the spacing 128 to different sizes of SIW circuits under test 102. As a result, a variety of SIW circuits under test 102 may be accommodated by the test fixture 114, making the latter reusable. Alignment apertures as in 132 may further be provided in the SIW circuit under test 102 for guiding a positioning thereof relative to the base member 118 and the fixation member 120. For this purpose, alignment bores as in 134, which correspond to the alignment apertures 132, may be machined into the base member 118. Coupling the SIW circuit under test 102 to the test fixture 114 may then comprise aligning apertures 132 and bores 134 to ensure proper positioning of the SIW circuit under test 102 relative to the base member 118 and the fixation member 120.

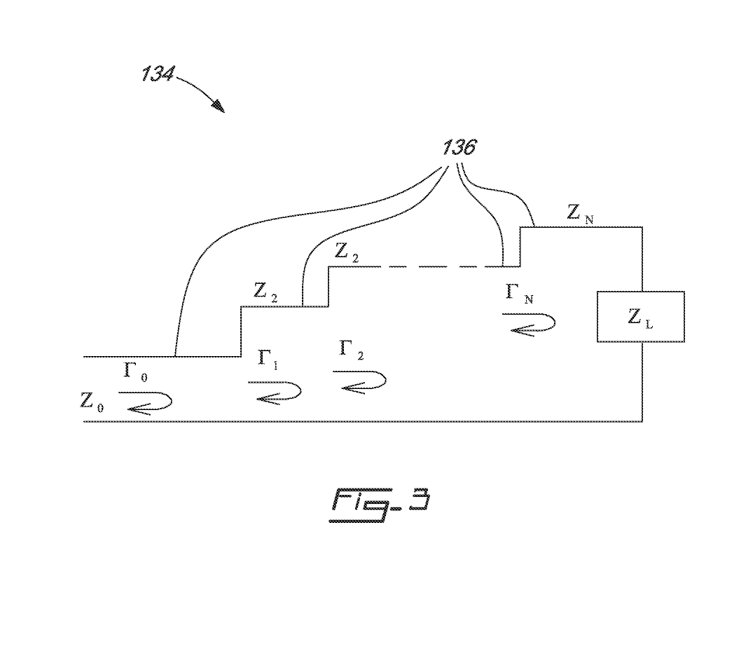

Referring to FIG. 3, a multi-section impedance matching transformer 134 may be provided in the fixation member 120 for ensuring the transition between the SIW circuit under test 102 and the waveguide 122. In particular, the transformer 134 may effect impedance transformation from the characteristic impedance of the SIW circuit under test 102 to the characteristic impedance of the waveguide 122. For this purpose, the transformer 134 may be formed by connecting N transmission line sections in series between the feeder transmission line of characteristic impedance Z₀ and the load impedance Z_{L}. As the impedance of the waveguide 122 and of the circuit under test 102 illustratively depend on the height and width of the transformer 134, the transformer 134 may be designed to comprise a plurality of steps 136 used for providing a transition between the height of the circuit under test 102 and the height of the waveguide 122.

Illustratively, four steps are designed so as to cover the bandwidth, illustratively 65 GHz to 110 GHz, of the waveguide 122 with 1% of power being reflected, i.e. not transmitted, between the SIW circuit under test 102 and the waveguide 122. The transition effected by the transformer 134 may indeed be optimized in such a way that multiple reflections between the SIW circuit under test 102 and the waveguide 122 are minimized. An H taper (not shown) may further be used to provide a transition between the width of the circuit under test 102 and the width of the waveguide 122. Different distributions, such as binomial linear or Chebyshev, may be used to implement the transformer 134. In this manner, a low loss transition with good matching over the entire bandwidth of the standard waveguide 122 of the first or second network analyzer component 106 or 108 may be achieved. Although a multi-section impedance matching transformer 134 has been described above, it should be understood that other transformers known to those skilled in the art may apply.

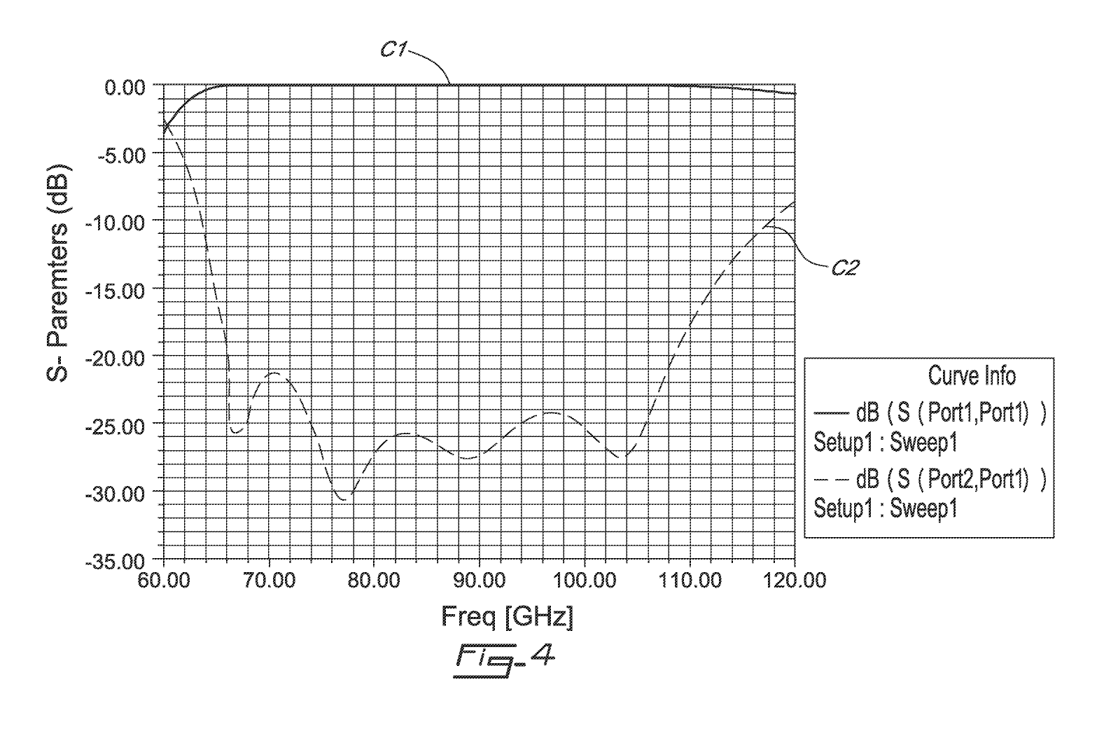

Referring to FIG. 4, simulations effected in a frequency range between 65 and 110 GHz exemplify the performance of the test fixture (reference 114 in FIG. 2b). The curve C1 illustrates the amount of power transferred between the SIW circuit under test (reference 102 in FIG. 2b) and the waveguide (reference 122 in FIG. 2b) connected via the test fixture 114. As can be seen from curve C1, the loss of power transmitted at the test fixture 114 is close to 0 dB in the frequency range between 65 GHz and 110 GHz. As such, substantially 100% of the energy is transmitted between the SIW circuit under test 102 and the waveguide 122. The curve C2 further illustrates the amount of power reflected between the SIW circuit under test 102 and the waveguide 122. As shown on curve C2, about −20 dB or 1% of the power is reflected at the test fixture 114.

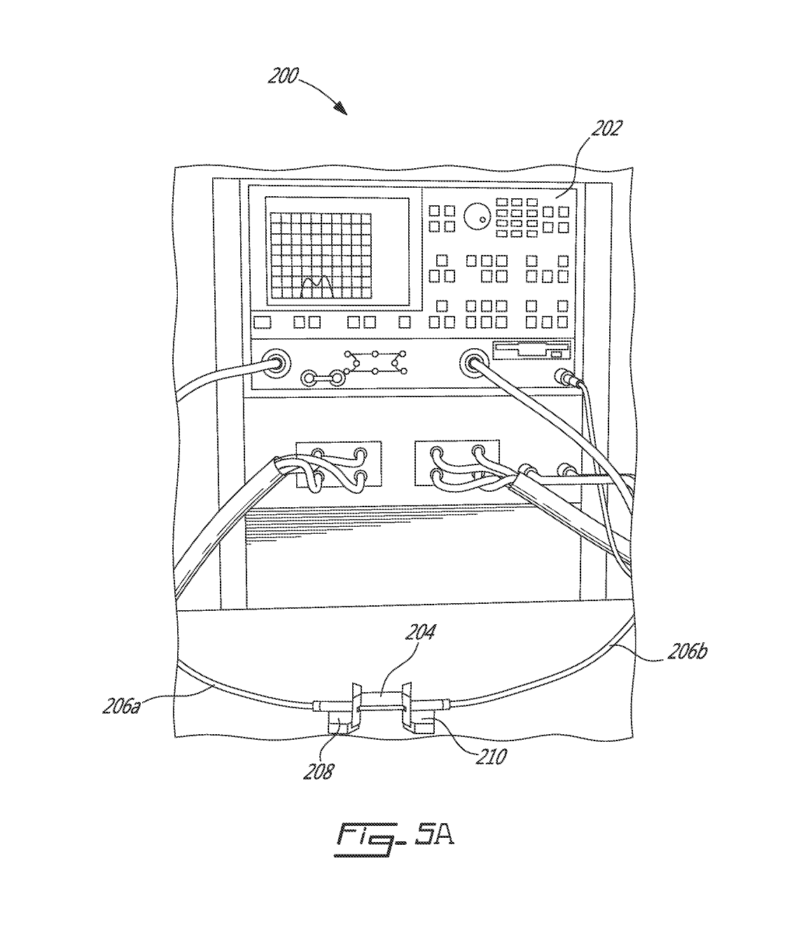

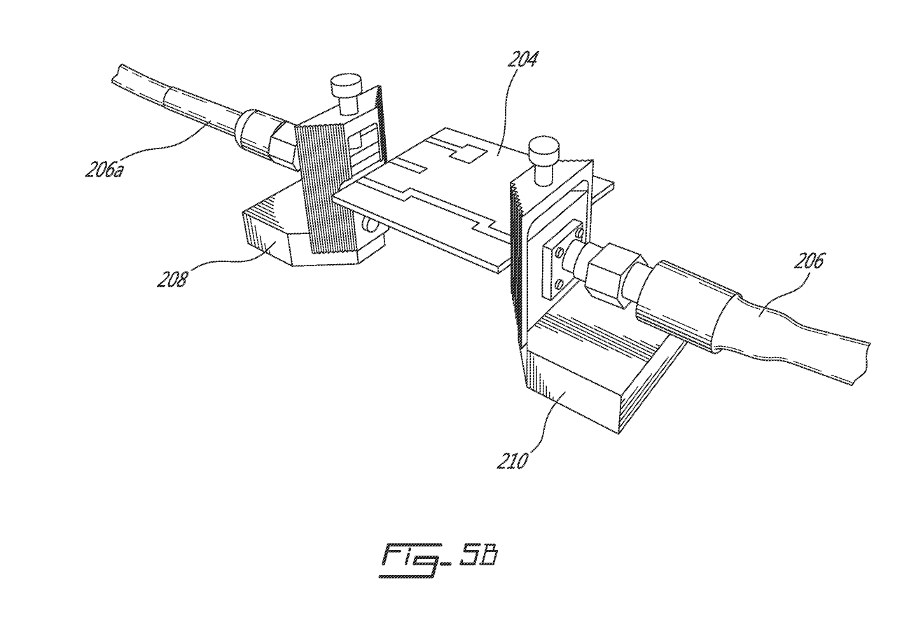

Referring to FIG. 5a and FIG. 5b, a test bench 200 for testing a planar circuit under test in accordance with a second illustrative embodiment will now be described. The test bench 200 may be used at low frequencies, e.g. below 65 GHz. The test bench 200 illustratively comprises test equipment 202, such as a network analyzer, which may be used for testing a planar circuit 204. The planar circuit 204 may be a SIW circuit, a microstrip circuit, a coplanar circuit, or the like, as discussed above. It should also be understood that test equipment 202 other than a network analyzer may apply. The test equipment 202 is illustratively a two-port vector analyzer, to which a device under test, such as the planar circuit 204, may be connected via coaxial cables as in 206a and 206b. A first and a second test fixture 208 and 210 may therefore be used to couple the circuit under test 204 to the test equipment 202. The first test fixture 208 is illustratively coupled to the test equipment 202 via cable 206a and to a first edge (not shown) of the circuit under test 204. The second test fixture 210 is illustratively coupled to the opposite edge (not shown) of the circuit under test 204 and to the test equipment 202 via cable 206b.

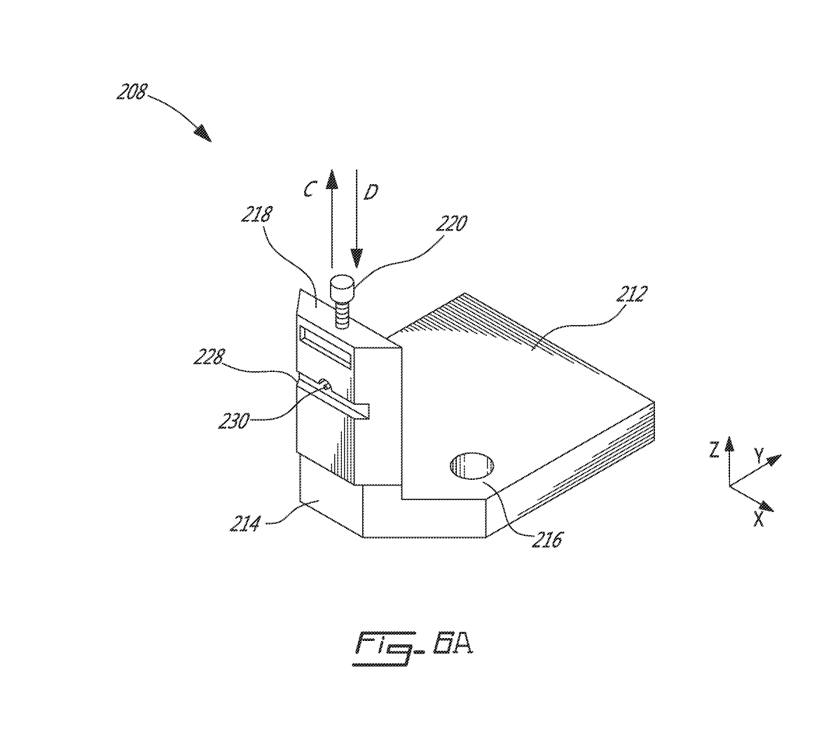

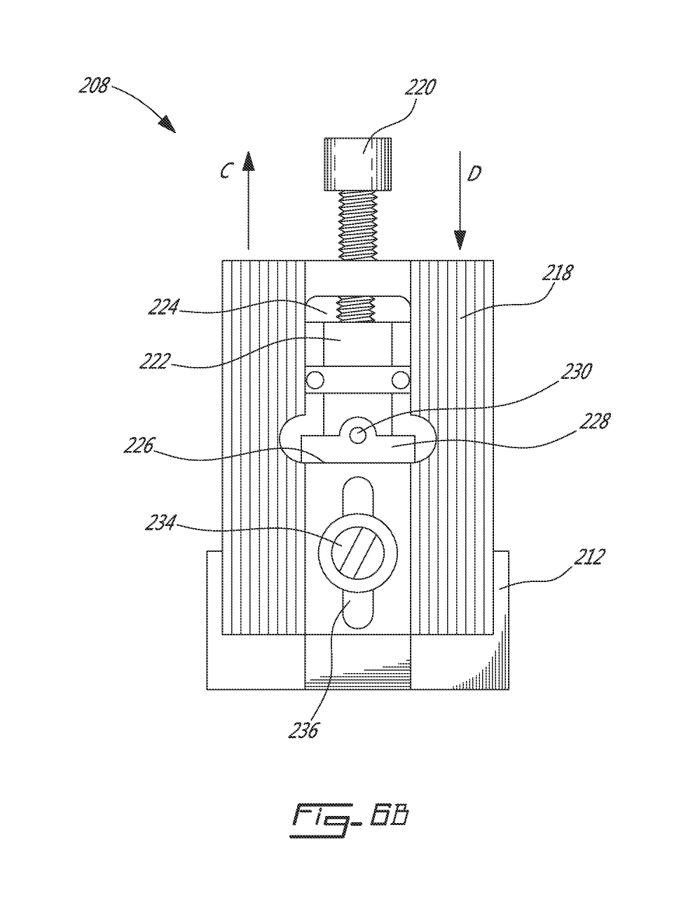

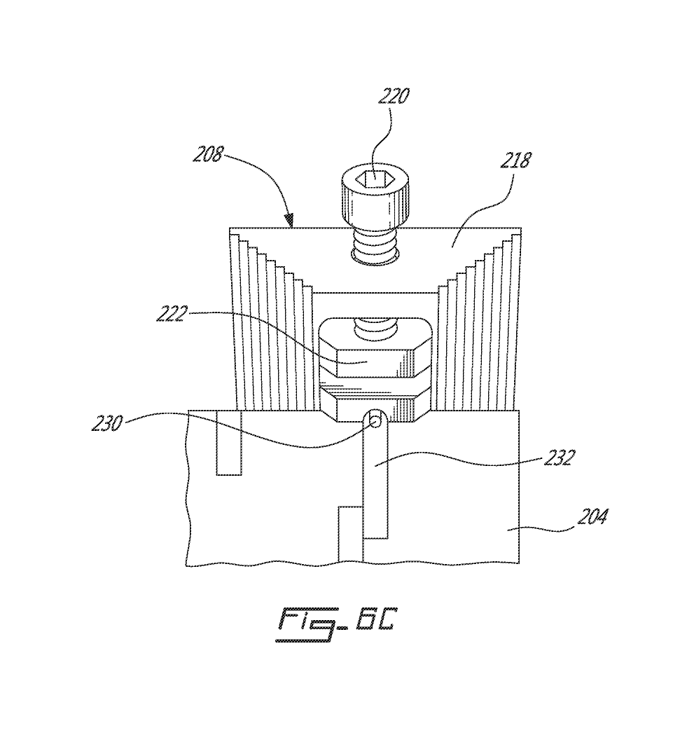

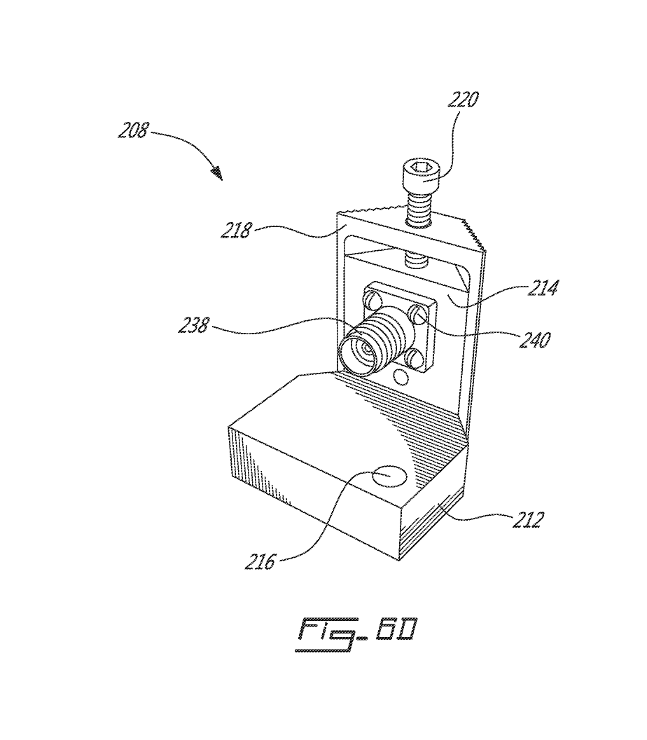

Referring to FIG. 6a, the first test fixture 208, which illustratively corresponds to the second test fixture 210, will now be described. The test fixture 208 illustratively comprises a substantially planar base member 212 and a support member 214 extending away from the base member 212 along the Z axis. The base member 212 and the support member 214 may be made of metal, such as aluminum, or any other suitable material known to those skilled in the art. The base member 212 may comprise a vacuum port 216 for allowing the use of vacuum pumping to firmly retain the test fixture 208 in place on a base plate or the like (not shown). It should be understood that other methods for holding the base member 212 in place may also apply. For example, the base member 212 may be made of a ferromagnetic material, such as steel, and a magnet may be assembled under the base plate onto which the test fixture 208 is positioned. In this manner, the test fixture 208 may attach to the base plate yet be movable thereon to relocate the test fixture 208 as desired on the base plate.

The support member 214 illustratively comprises a fixation member, such as a movable jaw 218, adapted to clamp the circuit under test 204 when the latter is coupled to the test fixture 208. For this purpose, a tightening member, such as a tightening screw 220 or the like, may be coupled to the jaw 218 for enabling a displacement of the jaw 218 along the Z axis. In particular, by loosening the screw 220, the jaw 218 may be allowed to move away from the base member 212 in the direction of arrow C or towards the base member 212 in the direction of arrow D. Once the desired position of the jaw 218 relative to the base member 212 has been achieved, the screw 220 may be tightened to secure the jaw 218 in position. The jaw 218 may be held in position by tightening the screw 220 such that an end (not shown) thereof abuts against an upper surface (not shown) of the support member 214. The jaw 218 may be displaced when the screw 220 is loosened such that the end of the screw 220 is moved away from the upper surface, thereby enabling movement of the jaw 218 and screw 220. It should be understood that other connections for enabling movement of the jaw 218 relative to the base member 212 may apply.

Referring to FIG. 6b in addition to FIG. 6a, the jaw 218 is illustratively in flush contact with the support member 214. The support member 214 illustratively comprises a protuberance 222, which protrudes through an opening 224 defined in the jaw 218. A spacing between an inner surface (not shown) of the protuberance 222 and a portion of the perimeter of the opening 224, e.g. an edge or surface 226, illustratively defines a port or snap circuit area 228 adapted to receive therein the circuit under test 204.

Referring to FIG. 6c in addition to FIG. 6b, the snap circuit area 228 may further be provided with a contact pin 230 secured to the support member 214 for enabling electrical contact to be made with the circuit under test 204 (and more particularly with an input or output line provided thereon) when the latter is received in the snap circuit area 228. The contact pin 230 may therefore provide the transition between the circuit under test 204 and the coaxial interface of coaxial cable 206a, and accordingly between the circuit under test 204 and the test equipment (not shown). The contact pin 230 illustratively protrudes below the inner surface of the protuberance 222 so as to ensure that an optimal contact is made with the circuit under test 204. In addition, the aperture or cutout (not shown) around the contact pin 230 illustratively has a diameter, which is larger than a width of a line 232, illustratively a 50 ohm input or output line, of the circuit under test 204. In this manner, improved electrical contact and a seamless transition between the circuit under test 204 and the coaxial cable 206a may be achieved.

The size of the snap circuit area 228 may be varied by loosening the screw 220 and displacing the jaw 218 along the direction of arrow C or arrow D, as discussed above. Indeed, displacing the jaw 218 along the direction of arrow C may increase the spacing between the inner surface of the protuberance 222 and the lower edge 226. The size of the snap circuit area 228 may accordingly be increased. Alternatively, the size of the snap circuit area 228 may be reduced by displacing the jaw 218 along the direction of arrow D. As a result, different circuits under test as in 204 having a variety of sizes may be accommodated by the test fixture 208, making the latter reusable. A fastener, such as a screw 234 may also be provided to further secure the jaw 218 in place once a desired position has been reached. For this purpose, a longitudinal slot 236 may be machined into the jaw 218 for receiving the screw 234 therein.

It should be understood that, in some embodiments, one of or both the screws 220, 234 may be provided to enable displacement of the jaw 218 relative to the base member 212 and to secure the jaw 218 in place. For instance, only the tightening screw 220 may be provided, which when loosened or tightened adjusts a positioning of the jaw 218, as discussed above. Alternatively, only the screw 234 may be provided, which when loosened enables displacement of the jaw 218 along arrows C or D of FIG. 6b and when tightened allows to secure the jaw 218 in the desired position. Cooperation of both fasteners 220, 234 can enable precise control of the positioning of the jaw 218. As discussed above, it should also be understood that any suitable connection means other than the fasteners 220, 234, may apply.

Referring to FIG. 6d, a coaxial port or connector 238 may be coupled to the support member 214 to allow the cable (reference 206a in FIG. 5b) to be coupled to the test fixture 208. The coaxial connector 238 may be attached to the support member 214 using fasteners, such as screws 240.

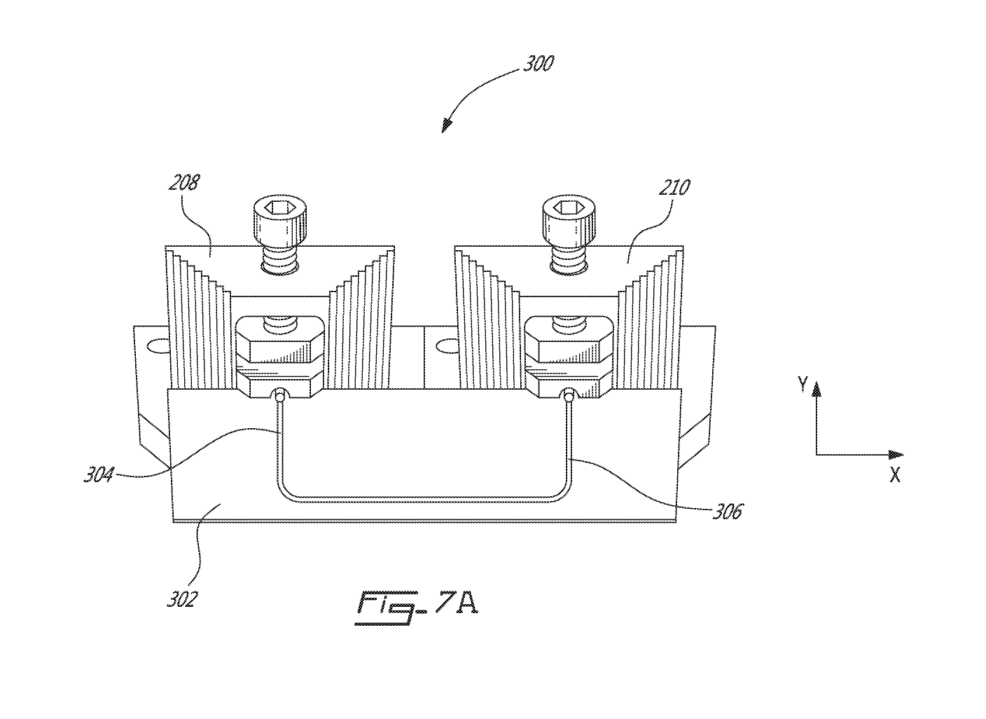

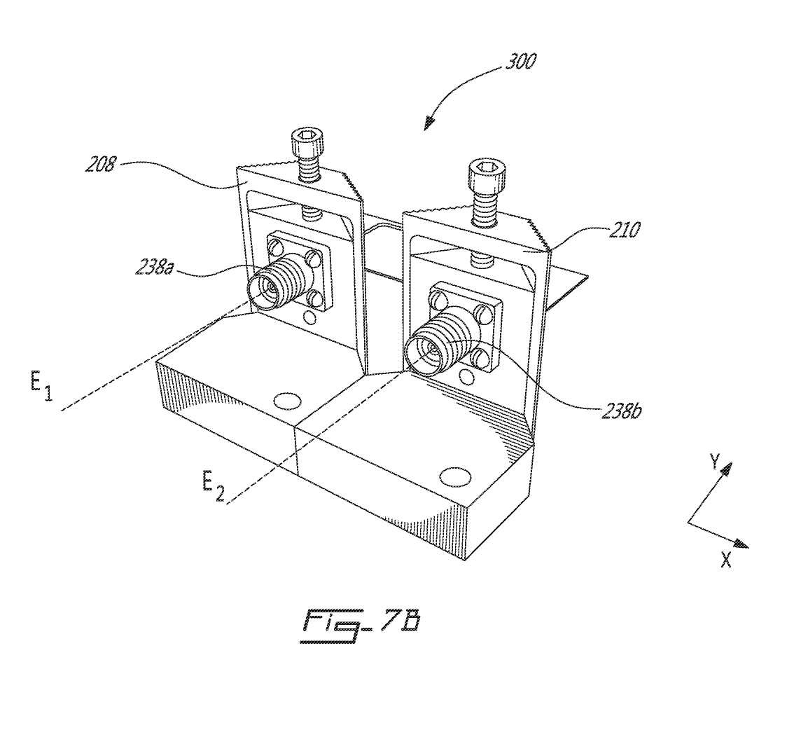

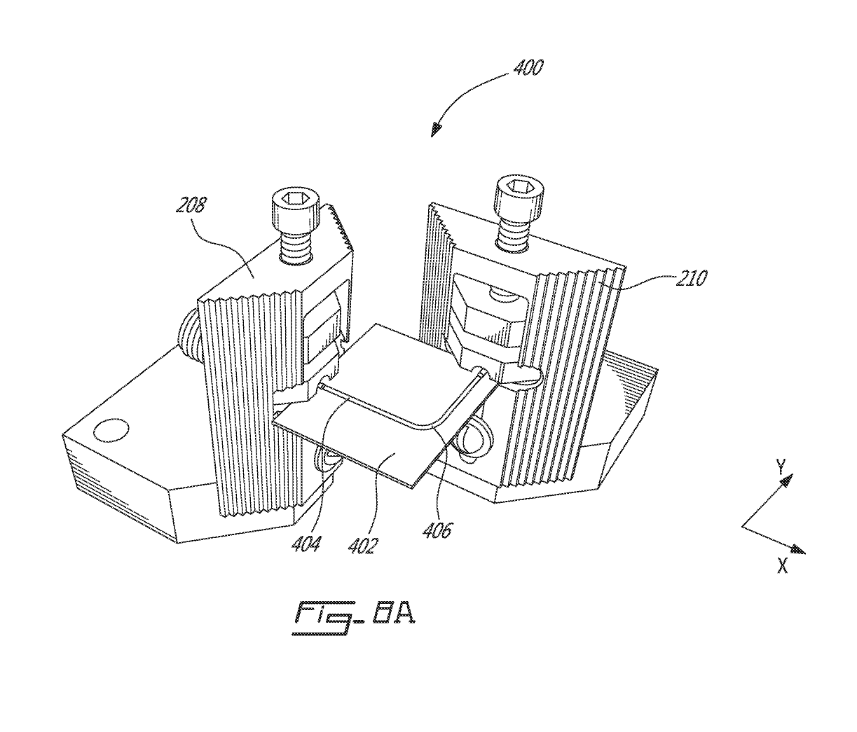

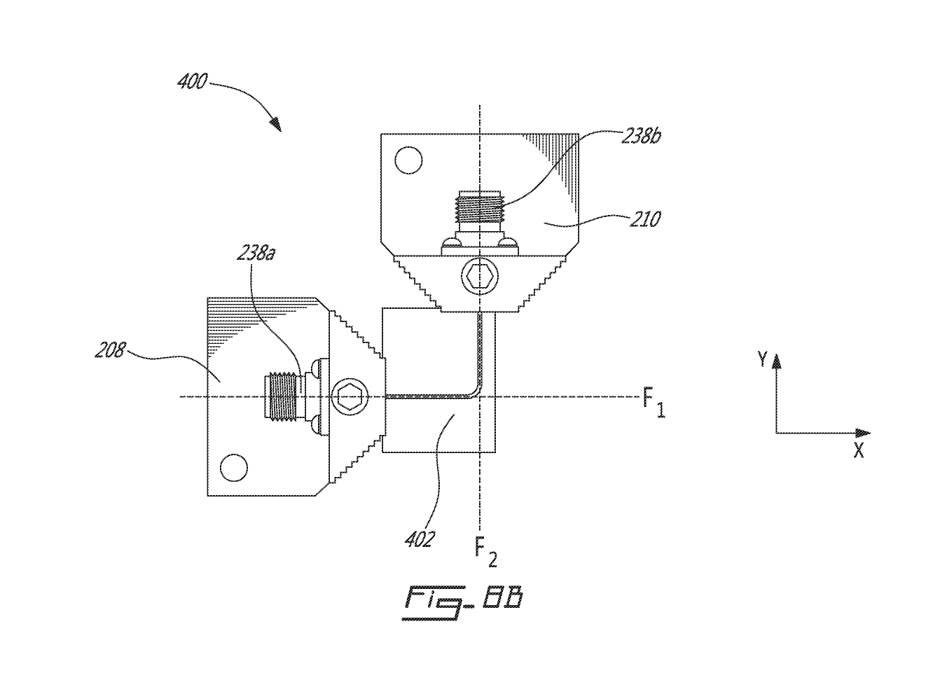

A plurality of test fixtures 114 or 208 may be positioned at various angles or orientations relative to one another so as to test a variety of circuits having different configurations. For example, referring to FIG. 7a and FIG. 7b, the test fixtures 208 and 210 may be arranged in a side-by-side arrangement 300. This may be desirable for testing a circuit under test 302 having parallel input and output lines 304, 306. For this purpose, the test fixtures 208 and 210 may be positioned such that their respective coaxial connectors 238a and 238b are both extending along directions E₁, E₂ substantially parallel to the direction of the Y axis. Referring to FIG. 8a and FIG. 8b, the test fixtures 208 and 210 may alternatively be arranged in an orthogonal configuration 400 for testing a circuit under test 402, e.g. a coupling unit, whose input and output lines 404, 406 are at substantially ninety (90) degrees. In the arrangement 400, the respective coaxial connectors 238a and 238b of test fixtures 208 and 210 may extend along substantially perpendicular directions F₁, F₂, with F₁ and F₂ substantially parallel to the direction of axes X and Y, respectively. It should be understood that numerous other geometries may be achieved.

In addition, provision of the fixation member 120 or 214 on the test fixture 114 or 208 not only enables circuits having various sizes to be tested but can also enable circuits under test to be positioned at varying heights relative to the waveguide 122 or the coaxial connector 238. In this manner, the test fixture 114 or 208 enables testing of hybrid or multilayer circuits. Also, the modularity of the test fixtures as in 114 or 208 allows for any number of test fixtures as in 114 or 208, and accordingly any number of ports, to be coupled to a given circuit. As such, multiport circuits may be tested. Although coaxial connectors are described herein, the test fixtures 114 or 208 may further be used with various connectors, such as K-connectors, V-connectors, APC-7 connectors, SMA connectors, or the like.

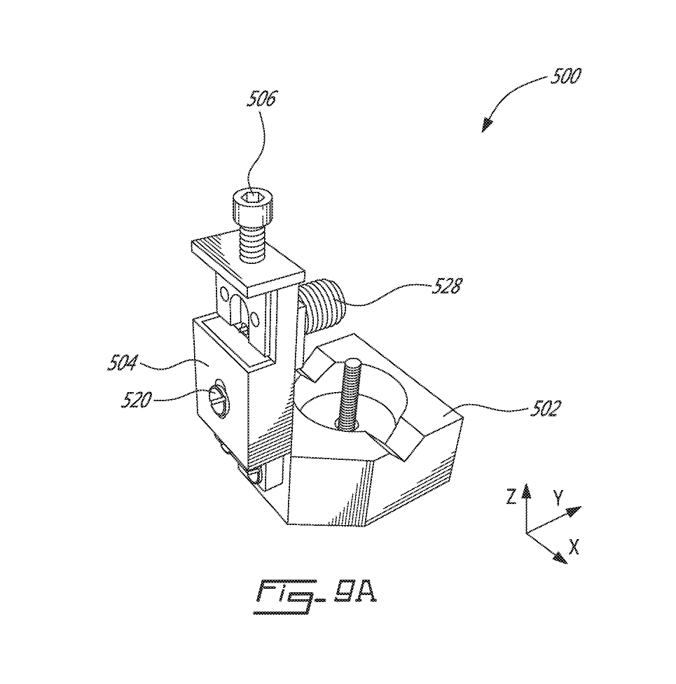

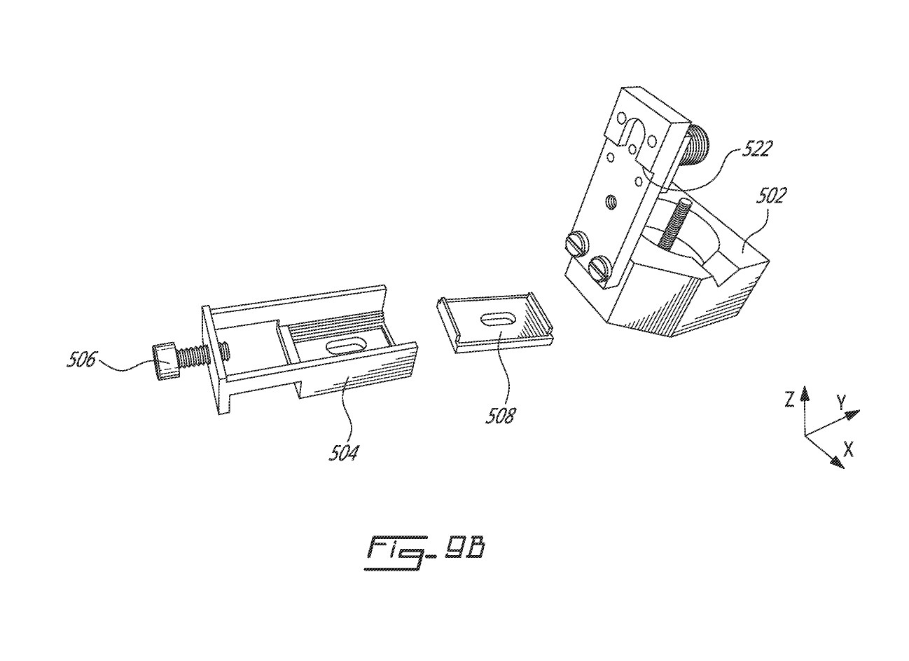

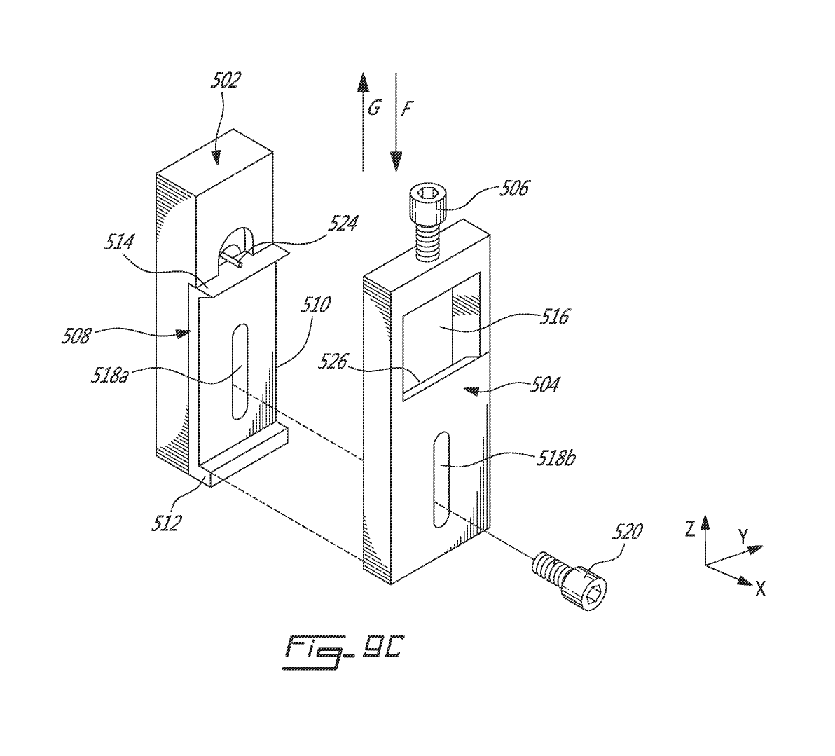

Referring to FIG. 9a and FIG. 9b, a test fixture 500 in accordance with in an alternative embodiment will now be described. The test fixture 500 comprises a base member 502 and a lever member 504 attached to the base member 502 using suitable fastening means, such as screws, or the like (not shown). The base member 502 and the lever member 504 are illustratively made of metal, such as aluminum or any other suitable material known to those skilled in the art. The lever member 504 has further formed at an upper end (not shown) thereof an aperture (not shown) adapted to receive therein a tightening member, such as a tightening screw 506.

Referring to FIG. 9c in addition to FIG. 9a and FIG. 9b, a contact member 508 may be further attached to the base member 502 and to the lever member 504, using any suitable means, as will be discussed further below. The contact member 508 may be made of metal or any other suitable material enabling electrical conductivity. The contact member 508 illustratively comprises a substantially planar body (not shown) having a base member contacting face (not shown) and a lever member contacting face 510 opposite the base member contacting face. A first edge 512 extends away from a first end (not shown) of the body of the contact member 508 along the X axis. The first edge 512 may be sized and shaped to support thereon a lower end (not shown) of the lever member 504. A second edge 514 illustratively extends away from a second end (not shown) of the body along the X axis, the second end being opposite the first end. The second edge 514 is illustratively beveled and is configured to be received in and cooperate with an opening 516 formed in the lever member 504. At least one elongate aperture or slot 518a is further formed in the body of the contact member 508 and extends longitudinally along the direction of the Z axis. The aperture 518a corresponds to and is configured to cooperate with at least one elongate aperture 518b, which is formed in the lever member 504 and extends longitudinally along the direction of the Z axis. Both apertures 518a, 518b may each be sized and shaped to receive therein a fastener 520, such as a screw. The apertures 518a, 518b may further be sized and shaped to allow longitudinal displacement along the Z axis of the lever member 504, and accordingly of the contact member 508, relative to the base member 502. It should be understood that other connections for enabling movement of the lever member 504 relative to the base member 502, e.g. connection means other than the screws 506, 520, may apply. Also, at least one of the screws 506, 520, may be provided.

When attaching the lever member 504 to the base member 502, the base member contacting face of the contact member 508 is illustratively first abutted against a contact member receiving face (not shown) of the base member 502. The lever member 504 is then positioned adjacent the exposed lever member receiving face 510 of the contact member 508 such that the apertures 518a and 518b are aligned. The screw 520 is then received in the aligned apertures 518a, 518b and may be tightened so as to retain the base member 502, the lever member 504, and the contact member 508 in place relative to one another. When so positioned, the lower end of the lever member 504 is supported on the second edge 512 while the beveled edge 514 is received within the opening 516.

The tightening screw 506 may then be actuated, e.g. loosened, for enabling displacement of the lever member 504 along the Z axis in the direction of arrow G. The lever member 504 may be displaced such that the beveled edge 524 rests against a portion of the perimeter of the opening 516, e.g. against a surface or edge 526 formed in the lever member 504. As a result, further displacement of the lever member 504 along the direction of arrow G causes concurrent displacement of the contact member 508 in the direction of arrow G. The beveled edge 514 may then be raised until it is abutted against a lower surface 522 (see FIG. 9b) of a protuberance (not shown) formed in the base member 502. It should be understood that a reverse displacement of the lever member 504 along the direction of arrow F may also be achieved. The displacement of the lever member 504 may be effected manually (or using any other suitable means) until a desired position is reached. The tightening screw 506 may then be actuated, e.g. tightened, to secure the position of the lever member 504 and of the contact member 508. With the beveled edge 514 abutting the lower surface 522 of the base member's protuberance, a circuit under test (not shown) may then be coupled to the test fixture 500 adjacent a contact pin 524 provided in the base member 502 adjacent the lower surface 522. In particular, at least a portion of the circuit under test may be supported on the edge 514 of the contact member 508. Using such a contact member 508 illustratively enables improved electrical contact to be made while the circuit under test is held in the test fixture 500.

Although not illustrated, the test fixture 500 may further comprise a fixation member, such as the movable jaw 218 illustrated in FIG. 6b, which enables to retain the circuit under test in the test fixture 500. For this purpose, the fixation member may be connected to the lever member 504 and the base member 502 and adapted to move relative thereto in a manner similar to that described with reference to FIG. 6a, FIG. 6b, and FIG. 6c. In this case, the apertures 518a, 518b, and the fasteners as in 520 received therein may not need to be provided separately from the aperture 236 and fastener 234 of FIG. 6b. In other words, the same aperture and fastener combination may be used to adjust the positioning of the lever member 504 and of the fixation member. A coaxial port or connector (reference 528 in FIG. 9a) may further be provided on the base member 502 to enable a cable (not shown) to be coupled to the test fixture 500. Other types of connectors, such as K-connectors, V-connectors, APC-7 connectors, SMA connectors, or the like, may also apply.

The embodiments of the invention described above are intended to be exemplary only. The scope of the invention is therefore intended to be limited solely by the scope of the appended claims.

1. A test fixture for testing a planar circuit, the test fixture comprising:
a body adapted to retain therein the planar circuit and to be connected to test equipment, the body providing a transition between the planar circuit and the test equipment and comprising
a base member having a first surface; and
a fixation member having a second surface and connected to the base member through a first connection allowing movement along a first axis of the fixation member relative to the base member, a spacing defined between the first surface and the second surface for retaining therein an end of the planar circuit, the fixation member movable along the first axis relative to the base member for adjusting the spacing.

2. The test fixture of claim 1, wherein the first connection comprises at least one fastener received in at least one slot formed in the fixation member, the at least one slot extending along the first axis and having a first dimension along the first axis greater than a second dimension of the at least one fastener along the first axis for enabling movement of the fixation member along the first axis, the at least one fastener adapted to be retained within the at least one slot during the movement of the fixation member along the first axis.

3. The test fixture of claim 2, wherein the planar circuit is a substrate-integrated waveguide circuit and further wherein the base member comprises a rectangular waveguide adapted to be connected to the test equipment.

4. The test fixture of claim 3, wherein the rectangular waveguide comprises a third surface substantially perpendicular to the first surface, the fixation member abutted against the third surface and movable relative thereto along the first axis.

5. The test fixture of claim 4, wherein the fixation member comprises a multi-section impedance matching transformer for effecting a transformation from a first characteristic impedance of the planar circuit to a second characteristic impedance of the waveguide, thereby providing the transition between the planar circuit and the test equipment.

6. The test fixture of claim 5, wherein the base member comprises at least one first aperture and the planar circuit comprises at least one second aperture corresponding to the at least one first aperture, the at least one second aperture adapted to be aligned with the at least one first aperture during insertion of the planar circuit within the spacing for adjusting a positioning of the planar circuit relative to the body.

7. The test fixture of claim 2, wherein the planar circuit is one of a substrate-integrated waveguide circuit, a microstrip circuit, and a coplanar waveguide circuit.

8. The test fixture of claim 7, further comprising a coaxial port secured to the base member and adapted to receive therein a coaxial cable for connecting the test equipment to the body.

9. The test fixture of claim 8, further comprising a contact pin connected to the base member adjacent the first surface, the contact pin providing the transition between the test equipment and the planar circuit retained within the spacing.

10. The test fixture of claim 9, wherein a cutout is formed in the base member for receiving the contact pin and further wherein the planar circuit comprises at least one electrical line having a width smaller than a diameter of the cutout.

11. The test fixture of claim 9, further comprising a contact member and a lever member connected to the base member through a second connection allowing movement of the contact member and of the lever member relative to the base member along the first axis, the contact member having an edge adapted to cooperate with a perimeter of the lever member for causing concurrent displacement of the contact member and of the lever member along the first axis.

12. The test fixture of claim 11, wherein the edge of the contact member is adapted to be positioned adjacent the contact pin as a result of the concurrent displacement of the contact member and of the lever member along the first axis, the planar circuit adapted to be supported on the contact member.

13. A test bench for testing a planar circuit, the test bench comprising:
a first test equipment and at least one second test equipment; and
a first test fixture and at least one second test fixture, the first test fixture comprising a first body adapted to retain therein a first end of the planar circuit and to be connected to the first test equipment and the at least one second test fixture comprising a second body adapted to retain therein a second end of the planar circuit opposite the first end and to be connected to the at least one second test equipment, the first and second body each comprising
a base member having a first surface, and
a fixation member having a second surface and connected to the base member through a first connection allowing movement along a first axis of the fixation member relative to the base member, a spacing defined between the first surface and the second surface for retaining therein a corresponding one of the first end and the second end of the planar circuit, the fixation member movable along the first axis relative to the base member for adjusting the spacing.

14. The test bench of claim 13, wherein the first body of the first test fixture comprises a first coaxial port secured to the base member of the first body and the second body of the at least one second test fixture comprises a second coaxial port secured to the base member of the second body, the first and the second coaxial ports each adapted to receive therein a coaxial cable for connecting a corresponding one of the first and the at least one second test equipment to a corresponding one the first and second body.

15. The test bench of claim 14, wherein the planar circuit comprises an input line extending away from the first end and at least one output line extending away from the second end, the at least one output line substantially parallel to the input line, and further wherein the first test fixture is positioned relative to the at least one second test fixture such that the first coaxial port of the first test fixture extends along a first direction and the second coaxial port of the at least one second test fixture extends along a second direction substantially parallel to the first direction.

16. The test bench of claim 14, wherein the planar circuit comprises an input line extending away from the first end and at least one output line extending away from the second end, the at least one output line oriented at an angle relative to the input line, and further wherein the first test fixture is positioned relative to the at least one second test fixture such that the first coaxial port of the first test fixture extends along a first direction and the second coaxial port of the at least one second test fixture extends along a second direction oriented relative to the first direction at the angle.

17. The test bench of claim 14, wherein the planar circuit comprises an input line extending away from the first end and along a second axis and at least one output line extending away from the second end and along the second axis and further wherein the first test fixture is positioned relative to the at least one second test fixture such that the first coaxial port of the first test fixture and the second coaxial port of the at least one second test fixture extend along the second axis.

18. A method for testing a planar circuit with a test fixture, the method comprising:
displacing along a first axis a fixation member of the test fixture relative to a base member of the test fixture, the fixation member connected to the base member through a first connection allowing movement along the first axis of the fixation member relative to the base member, the base member having a first surface and the fixation member having a second surface, a spacing defined between the first surface and the second surface and adapted to receive therein the planar circuit;
positioning the planar circuit within the spacing;
securing the fixation member in place relative to the base member, thereby retaining the planar circuit within the spacing; and
connecting test equipment to the test fixture for testing the planar circuit.

19. The method of claim 18, wherein displacing the fixation member relative to the base member comprises actuating in a first direction at least one fastener retained within at least one slot formed in the fixation member, the at least one slot extending along the first axis and having a first dimension along the first axis greater than a second dimension of the at least one fastener along the first axis for enabling movement of the fixation member along the first axis upon the at least one fastener being actuated in the first direction.

20. The method of claim 19, wherein securing the fixation member in place relative to the base member comprises actuating the at least one fastener in a second direction opposite to the first direction.
